(19) United States
(12) Patent Application Publication
(10) Pub. No.: US 2026/0111625 A1
(43) Pub. Date: Apr. 23, 2026

(54) SYSTEM-ON-CHIP-IN-THE-LOOP FOR CLOSED-LOOP SIMULATION OF A CONTROL SYSTEM

(71) Applicant: GM Global Technology Operations LLC, Detroit, MI (US)

(72) Inventors: Armando Antonio Beltran Pacheco, Rochester Hills, MI (US); Daniel J Berry, Macomb Township, MI (US); Milan Ashok Vadera, Auburn Hills, MI (US); Jatin Soni, South Lyon, MI (US)

(21) Appl. No.: 18/924,516

(22) Filed: Oct. 23, 2024

(51) Int. Cl. G06F 30/20

(52) U.S. Cl. CPC G06F 30/20

(57) ABSTRACT

A system-on-chip-in-the-loop (SoCIL) for closed-loop simulation of a control system includes a system-on-chip (SoC) field-programmable gate array (FPGA) board. The SoC FPGA board includes a target controller that is an electronic control unit (ECU). The target controller includes one or more target controller soft processors. The SoC FPGA includes a real-time computer that is a general-purpose computer. The real-time computer includes one or more real-time soft processors. The SoC FPGA includes one or more high-frequency simulation modules including a clock speed having a frequency in the Megahertz range and one or more high-frequency physical plant models. The one or more target controller soft processors of the target controller, the one or more real-time soft processors of the real-time computer, and the one or more high-frequency physical plant models of the one or more high-frequency simulation modules are in electronic communication with one another by an on-chip communication bus protocol.

### INTRODUCTION

The present disclosure relates to a system-on-chip-in-the-loop (SoCIL) system for closed-loop simulation of a control system. More particularly, the SoCIL is implemented on a system-on-chip (SoC) field-programmable gate array (FPGA) board that includes a plurality of soft processors.

Traditionally, real-time simulation systems have included an embedded controller having its own hardware and software architecture in combination with a software-based representation of the physical plant that is implemented by a general-purpose computer. The embedded controller and the general-purpose computer that implements the physical plant are integrated through hardwired connections, which are referred to as hardware in-the-loop (HIL). The term in-the-loop or in-loop means that parts of the software environment, such as the physical plant or hardware, are simulated. While hardware in-the-loop is efficient for testing control software interactions with hardware, hardware in-the-loop may face challenges in terms of integration and maintenance.

The original goal of hardware in-the-loop was to test real-time hardware interactions without the need for a physical plant. It is appreciated that hardware in-the-loop is extremely popular. However, not all software changes need to be verified through real-time simulations. As a result, in many instances hardware in-the-loop is used for applications that it was not originally intended for. There have been efforts to replace hardware in-the-loop system with other less complex virtual testing approaches. However, these less complex virtual testing approaches may face challenges such as fidelity, performance, and software reusability when attempting to integrate the virtual assets of each component within a system. For example, a virtual hardware in-the-loop system involves creating software-based emulations of hardware components and is referred to as a virtual electronic control unit (ECU). However, virtual electronic control units suffer from performance limitations when used in real-time applications. Virtual hardware in-the-loop systems also tend to have significantly slower execution times and lack the necessary hardware functionality for real-life testing applications.

Software-in-the-loop testing refers to testing embedded software either with or without an environment model using a general-purpose computer and does not utilize the hardware associated with an ECU. Software-in-the-loop simulations focus on evaluating software functionality, with limited hardware interface. Software-in-the-loop is widely used in automotive testing and makes it possible to test software prior to the initialization of the hardware prototyping phase, significantly accelerating the development cycle.

Thus, while current real-time simulation systems achieve their intended purpose, there is a need in the art for an in-the-loop simulation approach.

### SUMMARY

According to several aspects, a system-on-chip-in-the-loop (SoCIL) for closed-loop simulation of a control system is disclosed. The SoCIL includes a system-on-chip (SoC) field-programmable gate array (FPGA) board. The SoC FPGA board includes a target controller that is an electronic control unit (ECU), where the target controller includes one or more target controller soft processors. The SoC FPGA board includes a real-time computer that is a general-purpose computer, where the real-time computer includes one or more real-time soft processors. The SoC FPGA board includes one or more high-frequency simulation modules including a clock speed having a frequency in the Megahertz range and one or more high-frequency physical plant models. The one or more target controller soft processors of the target controller, the one or more real-time soft processors of the real-time computer, and the one or more high-frequency physical plant models of the one or more high-frequency simulation modules are in electronic communication with one another by an on-chip communication bus protocol.

In another aspect, the on-chip communication bus protocol is based on the Advanced Microcontroller Bus Architecture (AMBA) specification.

In yet another aspect, the on-chip communication bus protocol is one of the following: the advanced eXtensible interface (AXI) bus protocol, the advanced high-performance bus (AHB) protocol, the advanced peripheral bus (APB) protocol, the AXI coherency extensions (ACE), and the coherent hub interface (CHI).

In an aspect, the one or more high-frequency simulation modules include a fundamental step size that is measured in microseconds.

In another aspect, at least one of the one or more high-frequency physical plant models of the one or more high-frequency simulation modules represent a vehicular system.

In yet another aspect, the target controller is implemented based on a 32-bit reduced instruction set computer (RISC) architecture.

In an aspect, the one or more target controller soft processors execute one of the following: a specific real-time operating system and bare metal code.

In another aspect, the one or more target controller soft processors implement a board support package (BSP) that executes a Linux distribution operating system.

In yet another aspect, the real-time computer includes a simulator that executes one or more guest applications.

In an aspect, the one or more guest applications of the real-time computer each represent a physical plant model.

In another aspect, the physical plant model of the real-time computer represents a vehicular system.

In yet another aspect, the target controller executes one or more guest applications that each represent an algorithm that controls the one or more guest applications of the real-time computer.

In an aspect, the one or more high-frequency physical plant models of the high-frequency simulation modules are expressed in a hardware description language (HDL).

In another aspect, a SoCIL for closed-loop simulation of a control system is disclosed. The SoCIL includes a SoC FPGA board. The SoC FPGA board includes a target controller that is an electronic control unit (ECU), where the target controller includes one or more target controller soft processors. The SoC FPGA board includes a real-time computer that is a general-purpose computer, where the real-time computer includes one or more real-time soft processors. The SoC FPGA board includes one or more high-frequency simulation modules including a clock speed having a frequency in the Megahertz range and one or more high-frequency physical plant models, where the one or more high-frequency simulation modules include a fundamental step size that is measured in microseconds, and the one or more target controller soft processors of the target controller, the one or more real-time soft processors of the real-time computer, and the one or more high-frequency physical plant models of the one or more high-frequency simulation modules are in electronic communication with one another by an on-chip communication bus protocol that is based on the Advanced Microcontroller Bus Architecture (AMBA) specification.

In another aspect, the on-chip communication bus protocol is one of the following: the advanced eXtensible interface (AXI) bus protocol, the advanced high-performance bus (AHB) protocol, the advanced peripheral bus (APB) protocol, the AXI coherency extensions (ACE), and the coherent hub interface (CHI).

In yet another aspect, at least one of the one or more high-frequency physical plant models of the one or more high-frequency simulation modules represent a vehicular system.

In an aspect, the real-time computer includes a simulator that executes one or more guest applications.

In another aspect, the one or more guest applications of the real-time computer each represent a physical plant model.

In yet another aspect, the target controller executes one or more guest applications that each represent an algorithm that controls the one or more guest applications of the real-time computer.

In an aspect, a SoCIL for closed-loop simulation of a control system for a vehicle is disclosed. The SoCIL includes a SoC FPGA board. The SoC FPGA board includes a target controller that is an electronic control unit (ECU), where the target controller includes one or more target controller soft processors. The SoC FPGA board includes a real-time computer that is a general-purpose computer, where the real-time computer includes one or more real-time soft processors. The SoC FPGA board also includes one or more high-frequency simulation modules including a clock speed having a frequency in the Megahertz range and one or more high-frequency physical plant models that each represent a vehicular system. The one or more high-frequency simulation modules include a fundamental step size that is measured in microseconds. The one or more target controller soft processors of the target controller, the one or more real-time soft processors of the real-time computer, and the one or more high-frequency physical plant models of the one or more high-frequency simulation modules are in electronic communication with one another by an on-chip communication bus protocol that is based on the Advanced Microcontroller Bus Architecture (AMBA) specification.

Further areas of applicability will become apparent from the description provided herein. It should be understood that the description and specific examples are intended for purposes of illustration only and are not intended to limit the scope of the present disclosure.

### BRIEF DESCRIPTION OF THE DRAWINGS

The drawings described herein are for illustration purposes only and are not intended to limit the scope of the present disclosure in any way.

The FIGURE illustrates a schematic diagram of the disclosed system-on-chip-in-the-loop (SoCIL), according to an exemplary embodiment.

### DETAILED DESCRIPTION

The following description is merely exemplary in nature and is not intended to limit the present disclosure, application, or uses.

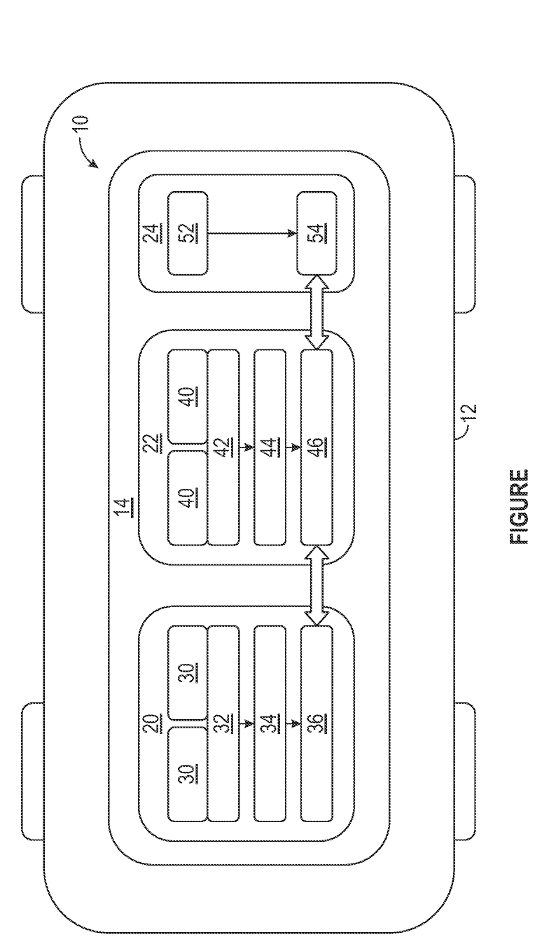

Referring to the FIGURE, a schematic diagram of the disclosed system-on-chip-in-the-loop (SoCIL) 10 for closed-loop simulation of a control system for a vehicle 12 is illustrated. The control system may represent any type of control system that includes one or more physical systems that the SoCIL 10 simulates such as, for example, an engine control system, one or more electric motors that provide motive power for the vehicle 12. It is appreciated that the vehicle 12 may be any type of vehicle such as, but not limited to, a sedan, a truck, sport utility vehicle, van, or motor home. It is also to be appreciated that while FIG.1 illustrates the SoCIL 10 as part of a vehicle such as an in-vehicle application for a software defined vehicle (SDV), the SoCIL 10 may be used in a variety of other applications as well. For example, in another embodiment, the SoCIL 10 may be employed during the design and development of the vehicle 12. Furthermore, it is to be appreciated that the SoCIL 10 is not limited to vehicles and may also be employed in applications such as, for example, aerospace and aeronautical applications. Merely by way of example, the SoCIL 10 may be used in avionics systems, flight management and navigation systems, flight control systems, aeronautical engine control systems, and aeronautical environmental control systems.

The SoCIL 10 includes a system-on-chip (SoC) field-programmable gate array (FPGA) board 14. It is to be appreciated that the SoCIL 10 refers to a closed-loop control system that is integrated into a SoC. The SoC FPGA board 14 includes a target controller 20, a real-time computer 22, and one or more high-frequency simulation modules 24. As explained below, the target controller 20 and the real-time computer 22 each include respective soft processors 36 and 46 that are implemented based on a soft processor architecture that allows for the execution of bare metal code in their hardware implementations. A soft processor architecture refers to a customizable microcontroller device that executes hardware description language (HDL). When deployed to gate-level hardware, the soft processor architecture functions as a real microcontroller that may be programmed as a microcontroller having a fixed architecture.

The target controller 20 is a production target controller, which is also referred to as an electronic control unit (ECU). In one embodiment, the target controller 20 is implemented based on a 32-bit reduced instruction set computer (RISC) architecture. The target controller 20 executes one or more user-level or guest applications 30. The target controller 20 also includes one or more lower-level software layers 32, one or more intermediate software layers 34, and one or more target controller soft processors 36.

The one or more guest applications 30 of the target controller 20 each represent an algorithm that controls one or more guest applications 40 that are executed by the real-time computer 22. One example of a programming language that may be used for the one or more guest applications 30 of the target controller 20 is the C programming language. The one or more guest applications 30 of the target controller 20 may be any algorithm for interacting with either the guest applications 40 executed by the real-time computer 22 as well as plant models or physical devices that are part of the SoC FPGA board 14 such as, for example, a diagnostic service algorithm, a library processing algorithm, and filters..

The one or more lower-level software layers 32 of the target controller 20 include one or more lower-level software layers such as, but not limited to, a board support package (BSP) layer, a basic software layer (BSW) layer, and a runtime environment (RTE). The one or more intermediate software layers 34 of the target controller 20 include one or more intermediate level software layers such as, but not limited to, a microcontroller abstraction layer. It is appreciated that the microcontroller abstraction layer is implemented for automotive or vehicle-based control applications.

The one or more target controller soft processors 36 of the target controller 20 implements an on-chip communication bus protocol to communicate with one or more peripheral devices located on the SoC FPGA board 14. Specifically, the one or more target controller soft processors 36 of the target controller 20 communicates with the one or more real-time soft processors 46 of the real-time computer 22 and one or more high-frequency physical plant models 52 of the high-frequency simulation modules 24 based on an on-chip communication bus protocol. In one embodiment, the on-chip communication bus protocol is based on the Advanced Microcontroller Bus Architecture (AMBA) specification. Some examples of the on-chip communication bus protocols that are based on the AMBA specification include, but are not limited to, the advanced eXtensible interface (AXI) bus protocol, the advanced high-performance bus (AHB) protocol, the advanced peripheral bus (APB) protocol, the AXI coherency extensions (ACE), and the coherent hub interface (CHI).

The one or more target controller soft processors 36 of the target controller 20 execute either a specific real-time operating system or bare metal code. Alternatively, in another embodiment, the one or more target controller soft processors 36 implement a board support package (BSP) that is customized to execute a Linux distribution operating system for more specific applications where a developer may need to access and configure the hardware of the entire SoC FPGA board 14 such as, for example, telecommunications equipment, aerospace systems, and defense systems.

The real-time computer 22 is a general-purpose computer. In one embodiment the real-time computer 22 includes a 64-bit architecture and executes a real-time Linux operating system. The real-time computer 22 executes the one or more guest applications 40. The real-time computer 22 includes a simulator 42, a host real-time operating system (RTOS) kernel 44, and one or more real-time soft processors 46. The one or more guest applications 40 of the real-time computer 22 each represent a physical plant model that is implemented as a mathematical model expressed in a programming language such as, for example, the C programming language. The physical plant model represents a physical system that the SoCIL 10 simulates. For example, in one embodiment, the physical plant model represents a vehicular system such as, for example, an engine, one or more electric motors for providing motive power to the vehicle 12

The simulator 42 of the real-time computer 22 is a simulation engine that executes the one or more guest applications 40. The RTOS kernel 44 of the real-time computer 22 manages the system resources of the real-time computer 22 such as the memory and devices. The one or more real-time soft processors 46 of the real-time computer 22 implements the on-chip communication bus protocol to communicate with one or more peripheral devices located on the SoC FPGA board 14, the one or more target controller soft processors 36 of the target controller 20, and the one or more high-frequency physical plant models 52of the one or more high-frequency simulation modules 24.

The one or more high-frequency simulation modules 24 include the one or more high-frequency physical plant models 52 and one or more peripheral devices 54. The one or more high-frequency simulation modules 24 includes a clock speed having a frequency in the Megahertz range and includes a fundamental step size that is measured in microseconds.

The one or more high-frequency physical plant models 52 of the high-frequency simulation modules 24 each represent a physical plant model that is implemented as a mathematical model expressed in a hardware description language such as, for example, very high-speed integrated circuit hardware description language (VHDL) or a hardware description language based on the Institute of Electrical and Electronics Engineers (IEEE) standard 1364 (VERILOG ®). As mentioned above, the physical plant model represents a physical system that the SoCIL 10 simulates. For example, in one embodiment, the physical plant model represents a vehicular system.

The one or more peripheral devices 54 of the one or more high-frequency simulation modules 24 implements the on-chip communication bus protocol to communicate between the one or more high-frequency physical plant models 52 and one or more peripheral devices located on the SoC FPGA board 14, the one or more target controller soft processors 36 of the target controller 20, and the one or more real-time soft processors 46 of the real-time computer 22. In other words, the one or more target controller soft processors 36 of the target controller 20, the one or more real-time soft processors 46 of the real-time computer 22, and the one or more one or more high-frequency physical plant models 52 of the one or more high-frequency simulation modules 24 are in electronic communication with one another by the on-chip communication bus protocol.

Referring generally to the FIGURE, the disclosed SoCIL provides various technical effects and benefits. Specifically, the disclosed SoCIL includes a fully integrated hardware design that enables real-time simulations on a single chip, while also maintaining the independence and modularity of the SoCIL’s internal components. The SoCIL also provides an approach for closed-loop simulation of multidomain control systems while addressing issues such as performance, fidelity, and reusability commonly encountered with current real-time simulation systems such as, for example, virtual hardware-in-the-loop. Specifically, by shifting from software-based emulations to hardware-based emulations, the SoCIL resolves the issue of hardware fidelity. Furthermore, the reusability issue is addressed by utilizing a soft processor architecture as part of the SoCIL, which allows for the execution of bare metal code in the SoCIL’s hardware implementation.

The modules may refer to, or be part of an electronic circuit, a combinational logic circuit, a field programmable gate array (FPGA), a processor (shared, dedicated, or group) that executes code, or a combination of some or all of the above, such as in a system-on-chip. Additionally, the modules may be microprocessor-based such as a computer having a at least one processor, memory (RAM and/or ROM), and associated input and output buses. The processor may operate under the control of an operating system that resides in memory. The operating system may manage computer resources so that computer program code embodied as one or more computer software applications, such as an application residing in memory, may have instructions executed by the processor. In an alternative embodiment, the processor may execute the application directly, in which case the operating system may be omitted.

The description of the present disclosure is merely exemplary in nature and variations that do not depart from the gist of the present disclosure are intended to be within the scope of the present disclosure. Such variations are not to be regarded as a departure from the spirit and scope of the present disclosure.

What is claimed is:

1. A system-on-chip-in-the-loop (SoCIL) for closed-loop simulation of a control system, the SoCIL comprising:
a system-on-chip (SoC) field-programmable gate array (FPGA) board, wherein the SoC FPGA board includes:
a target controller that is an electronic control unit (ECU), wherein the target controller includes one or more target controller soft processors;
a real-time computer that is a general-purpose computer, wherein the real-time computer includes one or more real-time soft processors; and
one or more high-frequency simulation modules including a clock speed having a frequency in the Megahertz range and one or more high-frequency physical plant models, wherein the one or more target controller soft processors of the target controller, the one or more real-time soft processors of the real-time computer, and the one or more high-frequency physical plant models of the one or more high-frequency simulation modules are in electronic communication with one another by an on-chip communication bus protocol.

2. The SoCIL of claim 1, wherein the on-chip communication bus protocol is based on the Advanced Microcontroller Bus Architecture (AMBA) specification.

3. The SoCIL of claim 1, wherein the on-chip communication bus protocol is one of the following: the advanced eXtensible interface (AXI) bus protocol, the advanced high-performance bus (AHB) protocol, the advanced peripheral bus (APB) protocol, the AXI coherency extensions (ACE), and the coherent hub interface (CHI).

4. The SoCIL of claim 1, wherein the one or more high-frequency simulation modules include a fundamental step size that is measured in microseconds.

5. The SoCIL of claim 1, wherein at least one of the one or more high-frequency physical plant models of the one or more high-frequency simulation modules represents a vehicular system.

6. The SoCIL of claim 1, wherein the target controller is implemented based on a 32-bit reduced instruction set computer (RISC) architecture.

7. The SoCIL of claim 1, wherein the one or more target controller soft processors execute one of the following: a specific real-time operating system and bare metal code.

8. The SoCIL of claim 1, wherein the one or more target controller soft processors implement a board support package (BSP) that executes a Linux distribution operating system.

9. The SoCIL of claim 1, wherein the real-time computer includes a simulator that executes one or more guest applications.

10. The SoCIL of claim 9, wherein the one or more guest applications of the real-time computer each represent a physical plant model.

11. The SoCIL of claim 10, wherein the physical plant model of the real-time computer represents a vehicular system.

12. The SoCIL of claim 10, wherein the target controller executes one or more guest applications that each represent an algorithm that controls the one or more guest applications of the real-time computer.

13. The SoCIL of claim 1, wherein the one or more high-frequency physical plant models of the high-frequency simulation modules are expressed in a hardware description language (HDL).

14. A SoCIL for closed-loop simulation of a control system, the SoCIL comprising:
a SoC FPGA board, wherein the SoC FPGA board includes:
a target controller that is an electronic control unit (ECU), wherein the target controller includes one or more target controller soft processors;
a real-time computer that is a general-purpose computer, wherein the real-time computer includes one or more real-time soft processors; and
one or more high-frequency simulation modules including a clock speed having a frequency in the Megahertz range and one or more high-frequency physical plant models, wherein the one or more high-frequency simulation modules include a fundamental step size that is measured in microseconds, and wherein the one or more target controller soft processors of the target controller, the one or more real-time soft processors of the real-time computer, and the one or more high-frequency physical plant models of the one or more high-frequency simulation modules are in electronic communication with one another by an on-chip communication bus protocol that is based on the Advanced Microcontroller Bus Architecture (AMBA) specification.

15. The SoCIL of claim 14, wherein the on-chip communication bus protocol is one of the following: the advanced eXtensible interface (AXI) bus protocol, the advanced high-performance bus (AHB) protocol, the advanced peripheral bus (APB) protocol, the AXI coherency extensions (ACE), and the coherent hub interface (CHI).

16. The SoCIL of claim 14, wherein at least one of the one or more high-frequency physical plant models of the one or more high-frequency simulation modules represents a vehicular system.

17. The SoCIL of claim 14, wherein the real-time computer includes a simulator that executes one or more guest applications.

18. The SoCIL of claim 17, wherein the one or more guest applications of the real-time computer each represent a physical plant model.

19. The SoCIL of claim 18, wherein the target controller executes one or more guest applications that each represent an algorithm that controls the one or more guest applications of the real-time computer.

20. A SoCIL for closed-loop simulation of a control system for a vehicle, the SoCIL comprising:
a SoC FPGA board, wherein the SoC FPGA board includes:
a target controller that is an electronic control unit (ECU), wherein the target controller includes one or more target controller soft processors;
a real-time computer that is a general-purpose computer, wherein the real-time computer includes one or more real-time soft processors; and
one or more high-frequency simulation modules including a clock speed having a frequency in the Megahertz range and one or more high-frequency physical plant models, wherein at least one of the high-frequency physical plant models represent a vehicular system, wherein the one or more high-frequency simulation modules include a fundamental step size that is measured in microseconds, and wherein the one or more target controller soft processors of the target controller, the one or more real-time soft processors of the real-time computer, and the one or more high-frequency physical plant models of the one or more high-frequency simulation modules are in electronic communication with one another by an on-chip communication bus protocol that is based on the Advanced Microcontroller Bus Architecture (AMBA) specification.
